(19) United States
(12) Patent Application Publication
(10) Pub. No.: US 2025/0005404 A1
(43) Pub. Date: Jan. 2, 2025

(54) DECISION PROCESSING SYSTEM AND DECISION PROCESSING METHOD

(71) Applicants: Digiwin Software Co., Ltd, Shanghai (CN); DATA SYSTEMS CONSULTING CO., LTD., New Taipei City (TW)

(72) Inventors: Qun Luo, Shanghai (CN); Guoxin Sun, Shanghai (CN)

(73) Assignees: Digiwin Software Co., Ltd, Shanghai (CN); DATA SYSTEMS CONSULTING CO., LTD., New Taipei City (TW)

(21) Appl. No.: 18/460,606

(22) Filed: Sep. 4, 2023

(30) Foreign Application Priority Data
Jun. 30, 2023 (CN) 202310803398.1

(51) Int. Cl. G06N 5/045

(52) U.S. Cl. CPC G06N 5/045

(57) ABSTRACT

The invention provides a decision processing system and a decision processing method. The decision processing system includes an electronic device and a server. The electronic device acquires target input data and application input data. The server includes a memory and a processor. The memory stores a plurality of models and task metadata. The processor executes the plurality of models. The design decision model computes the task metadata according to the target input data to generate a plurality of heterogeneous data nodes, and executes an encapsulation operation on the plurality of selected heterogeneous data nodes to generate a decision project. The action decision model executes the decision project according to the application input data to generate a decision result to the electronic device, so as to establish the decision project suitable for an abnormal condition to improve operation efficiency.

### CROSS-REFERENCE TO RELATED APPLICATION

This application claims the priority benefit of China application serial no. 202310803398.1, filed on Jun. 30, 2023. The entirety of the above-mentioned patent application is hereby incorporated by reference herein and made a part of this specification.

### BACKGROUND OF THE INVENTION

### Field of the Invention

The invention relates to a processing system, in particular to a decision processing system and a decision processing method using data-driven programming.

### Description of Related Art

A system applying data-driven programming may build an executable task from data. Since the external environment such as personnel and materials affect the task in execution, the process of the task is abnormal. In order to solve the above abnormality, the current system obtains a plurality of possible solutions via applications such as semantic search, question answering, and recommendation according to the enterprise knowledge base. However, the solutions still require manual judgment to obtain useful solutions, and the anomalies in the process may not be effectively eliminated, thereby reducing the efficiency of performing tasks.

### SUMMARY OF THE INVENTION

The invention is aimed at a decision processing system applying data-driven programming and may establish a decision project suitable for an abnormal condition, so as to improve operation efficiency.

According to an embodiment of the invention, a decision processing system of the invention includes an electronic device and a server. The electronic device acquires target input data and application input data. The server is coupled to the electronic device. The server includes a memory and a processor. The memory stores a plurality of models and task metadata. The processor is coupled to the memory and executes the plurality of models. The plurality of models include a design decision model and an action decision model. The design decision model computes the task metadata according to the target input data to generate a plurality of heterogeneous data nodes, and executes an encapsulation operation on the plurality of selected heterogeneous data nodes to generate a decision project. The action decision model executes the decision project according to the application input data to generate a decision result to the electronic device.

According to an embodiment of the invention, a decision processing method of the invention includes the following steps. Target input data and application input data are acquired via an electronic device. A plurality of models stored in a memory of a server are executed via a processor of the server. The plurality of models include a design decision model and an action decision model. The step of executing the plurality of models includes the following steps. Task metadata stored in the memory is computed according to the target input data via the design decision model to generate a plurality of heterogeneous data nodes. An encapsulation operation is executed on the plurality of selected heterogeneous data nodes via the design decision model to generate a decision project. The decision project is executed according to the application input data via the action decision model to generate a decision result to the electronic device.

Based on the above, the decision processing system and the decision processing method of the invention may acquire various structured data related the abnormal condition by generating the heterogeneous data nodes according to the target input data and the task metadata. By encapsulating the selected structured data (i.e., the heterogeneous data nodes), the decision processing system may acquire the executable decision project, so as to eliminate the corresponding abnormality based on the decision project when executing any application task. In this way, the knowledge management system may pass on knowledge and experience and improve the operation efficiency of performing a task.

In order to make the above features and advantages of the invention better understood, embodiments are specifically provided below with reference to figures for detailed description as follows.

### BRIEF DESCRIPTION OF THE DRAWINGS

FIG. 1 is a circuit block diagram of a decision processing system of an embodiment of the invention.

FIG. 2 is a flowchart of a decision processing method of an embodiment of the invention.

FIG. 3A is a schematic diagram of an action of a decision processing system of an embodiment of the invention.

FIG. 3B is a schematic diagram of a plurality of heterogeneous data nodes of the embodiment of FIG. 3A of the invention.

FIG. 4 is a schematic diagram of an action of a decision processing system of an embodiment of the invention.

FIG. 5 is a schematic diagram of an action of a decision processing system of another embodiment of the invention.

FIG. 6 is a schematic diagram of a decision project of an embodiment of the invention.

### DESCRIPTION OF THE EMBODIMENTS

Reference will now be made in detail to the exemplary embodiments of the invention, examples of which are illustrated in the accompanying drawings. Wherever possible, the same reference numerals are used in the drawings and descriptions to refer to the same or like portions.

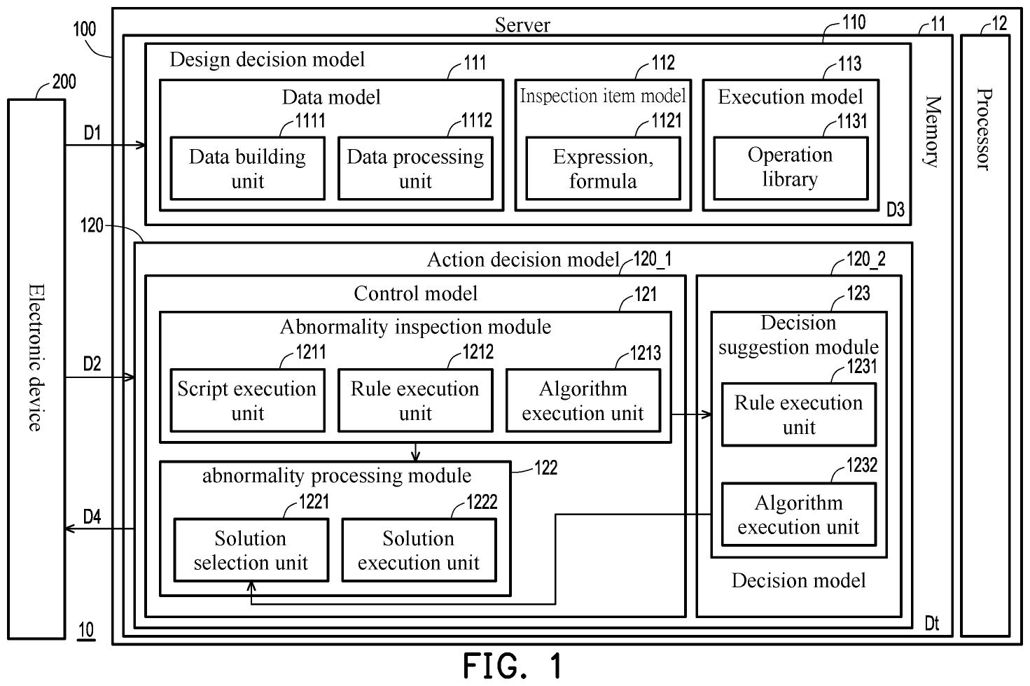

FIG. 1 is a circuit block diagram of a decision processing system of an embodiment of the invention. Referring to FIG. 1, a decision processing system 10 applies data-driven programming and a knowledge graph. The decision processing system 10 automatically proposes and executes a decision project D3 that may resolve abnormal flow. In the present embodiment, the decision processing system 10 may include a server 100 and an electronic device 200. The electronic device 200 is coupled to the server 100.

In the present embodiment, the user may operate the electronic device 200 to call the server 100 via an application programming interface (API). The user may also operate the electronic device 200 to call the enterprise system via the API, and then execute various business services via the enterprise system. The electronic device 200 may be, for example, a mobile phone, a tablet computer, a notebook computer, a desktop computer, and the like. The enterprise system may be, for example, an enterprise resource planning (ERP) system (hereinafter, an ERP system is used as an example for description).

In the present embodiment, the server 100 may include a memory 11 and a processor 12. The memory 11 stores a plurality of models 110 to 120 and task metadata Dt. The models may include the design decision model 110 and the action decision model 120. The task metadata Dt may be, for example, reference data associated with various processes used by the ERP system to provide business services, and is structured and defined reference data.

In the present embodiment, the memory 11 may also store computing software, etc., used to implement related algorithms, programs, and data related to functions such as data-driven programming, software design, software packaging, various calculations, and software execution of the invention. The memory 11 may be, for example, a dynamic random-access memory (DRAM), a flash memory, or a non-volatile random-access memory (NVRAM), and the invention is not limited thereto.

In the present embodiment, the processor 12 is coupled to the memory 11. The processor 12 accesses the memory 11, and may execute the data in the memory 11 and the models 110 to 120, and data from the electronic device 200 (such as a target input data D1 and an application input data D2). The processor 12 may be, for example, a signal converter, a field-programmable gate array (FPGA), a central processing unit (CPU), or other programmable general-purpose or special-purpose microprocessors, digital signal processors (DSPs), programmable controllers, application-specific integrated circuits (ASICs), programmable logic devices (PLDs), or other similar devices or a combination of the devices that may load and execute computer program-related firmware or software to implement functions such as data-driven programming, software design, software packaging, various calculations, and software execution.

In the present embodiment, the processor 12 executes the design decision model 110 during software design, so that the design decision model 110 generates and provides the decision project D3 that may resolve anomalies according to the target input data D1. The design decision model 110 may include a data model 111, an inspection item model 112, and an execution model 113.

In the present embodiment, the processor 12 executes the action decision model 120 during the actual application, so that the action decision model 120 executes an executable project (e.g., the decision project D3) according to the application input data D2 and provides a result after the project is executed (e.g., a decision result D4). The action decision model 120 may include a control model 120_1 and a decision model 120_2. The control model 120_1 may include an abnormality inspection module 121 and an abnormality processing module 122. The decision model 120_2 may include a decision suggestion module 123.

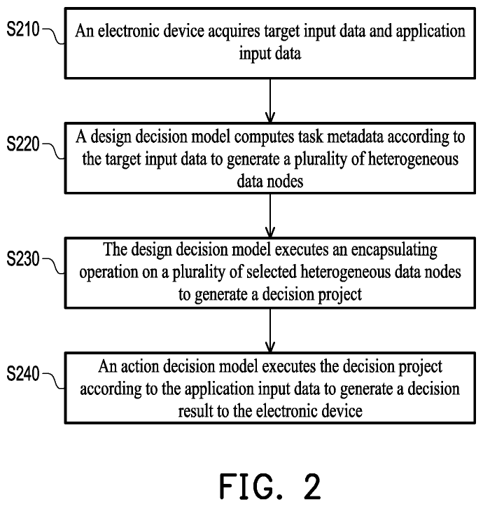

FIG. 2 is a flowchart of a decision processing method of an embodiment of the invention. Referring to FIG. 1 and FIG. 2, the decision processing system 10 may execute steps S210 to S250. The order of the steps S210 to S250 is only an example for illustration, and is not limited thereto. In the present embodiment, steps S210 to S250 may be applied to the following exemplary situations.

In step S210, the electronic device 200 acquires the target input data D1 and the application input data D2. In detail, during software design, the electronic device 200 accesses the ERP system to acquire the target input data D1. The target input data D1 may be, for example, an item that a user (or an enterprise) wants to solve and/or control. During actual application, the electronic device 200 accesses the ERP system to acquire the application input data D2. The application input data D2 may be, for example, routine data generated when an abnormality occurs in the process of the ERP system during execution, such as a purchase order or a purchase requisition in which an abnormality occurs.

During software design, the processor 12 executes the design decision model 110 stored in the memory 11. The processor 12 cooperates with the electronic device 200 to enable the server 100 and the user to interactively design the decision project D3 for solving the abnormal process.

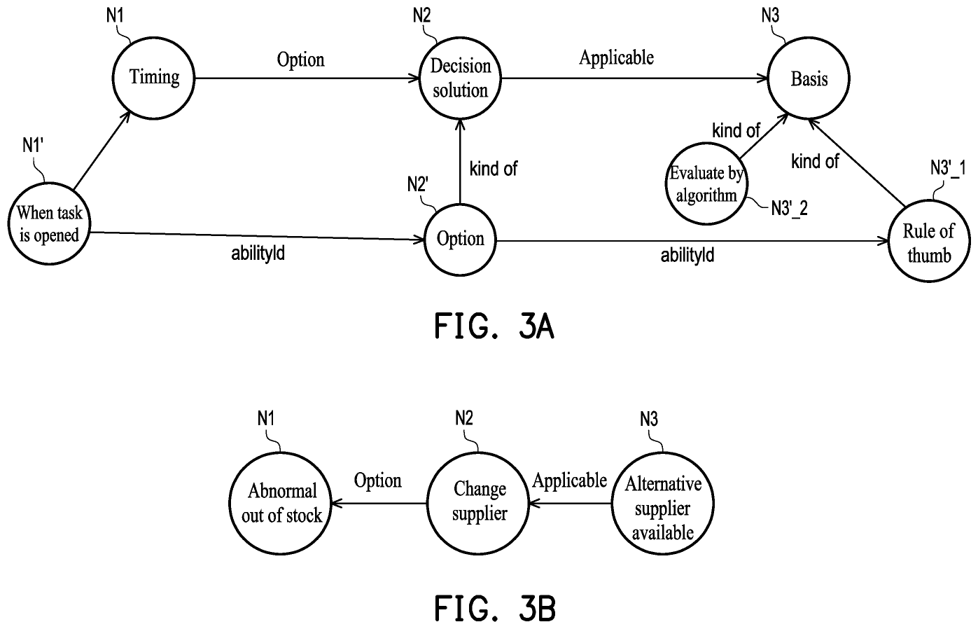

Specifically, in step S220, the processor 12 executes the design decision model 110 so that the design decision model 110 computes the task metadata Dt according to the target input data D1 to generate a plurality of heterogeneous data nodes (e.g., data nodes N1 to N3 shown in FIG. 3A or FIG. 3B). The heterogeneous data nodes may, for example, be data structured and processed knowledge graph data.

In detail, the processor 12 executes the data model 111 and the inspection item model 112 in the design decision model 110. The data model 111 executes data structuring on the task metadata Dt via a data building unit 1111 according to the target input data D1, so as to establish knowledge map data. The data model 111 executes data processing on the knowledge graph data via the data processing unit 1112 to generate a plurality of active data nodes. The data processing may include calculations without conditional formulas such as mathematical calculations, sampling, or a combination of the above.

Continuing with the above description, the inspection item model 112 accesses expressions and formulas 1121 in the memory 11. The inspection item model 112 computes a plurality of active data nodes with reference to the expressions and formulas 1121 to check whether the data nodes conform to the process specification of the corresponding business service. When the check is passed, the inspection item model 112 outputs the plurality of active data nodes as a plurality of heterogeneous data nodes.

In step S230, the processor 12 executes the design decision model 110, so that the design decision model 110 executes an encapsulating operation on the plurality of selected heterogeneous data nodes to generate the decision project D3. The decision project D3 may be, for example, an executable program associated with the target input data D1 to indicate the flow of matters to be resolved and/or controlled by the user (or enterprise). The decision project D3 complies with data-driven programming and is compiled.

In detail, the user operates the electronic device 200 to select a portion of the plurality of heterogeneous data nodes from the plurality of heterogeneous data nodes in step S220 via the server 100. The selected heterogeneous data nodes are used as data structures for solving an abnormal process. The processor 12 executes the execution model 113 in the design decision model 110. The execution model 113 translates the selected heterogeneous data nodes into an executable data structure (i.e., the decision project D3).

During actual application, the processor 12 executes the action decision model 120 stored in the memory 11. The processor 12 cooperates with the electronic device 200 so that the server 100 execute a corresponding abnormality processing program (i.e., the decision project D3) for the abnormal process.

Specifically, in step S240, the processor 12 executes the action decision model 120 so that the action decision model 120 executes the decision project D3 according to the application input data D2 to generate the decision result D4 to the electronic device 200. The decision result D4 may be, for example, the result of execution with reference to the standard process (for example, the decision project D3) of an established matter for an abnormal situation (for example, the application input data D2). For example, it is assumed that the decision project D3 includes sending an email to a supervisor via the processor when an abnormal event occurs. At this time, the control and decision model 120 is executed to send an email as the decision result D4 to the electronic device 200 operated by the supervisor.

In detail, the processor 12 executes the abnormality inspection module 121, the abnormality processing module 122, and the decision suggestion module 123 in the action decision model 120. The abnormality inspection module 121 checks whether the event indicated by the application input data D2 is abnormal via a script execution unit 1211, a rule execution unit 1212, and an algorithm execution unit 1213 to trigger an abnormality process. When the checking result is normal, the abnormality processing module 122 and the decision suggestion module 123 are not triggered. On the other hand, when the checking result is abnormal, the abnormality processing module 122 and the decision suggestion module 123 are triggered.

Continuing with the above description, the decision suggestion module 123 accesses one or a plurality of projects capable of resolving an abnormal process via the rule execution unit 1231 and the algorithm execution unit 1232. The abnormality processing module 122 selects the decision project D3 according to the application input data D2 via the solution selection unit 1221. The abnormality processing module 122 executes the selected decision project D3 via the solution execution unit 1222, and generates an executed result (e.g., the feedback result D4) to be fed back to the electronic device 200.

It is worth mentioning here that by designing the decision model 110 to establish the plurality of structured heterogeneous data nodes according to the target input data D1 and the task metadata Dt, the decision processing system 10 may precipitate and encapsulate the abnormal process with a knowledge graph, so as to implement the inheritance of knowledge and experience. Moreover, by designing the decision model 110 and the user to interactively design the executable decision project D3 according to the plurality of heterogeneous data nodes, the decision processing system 10 may eliminate the corresponding abnormality based on the decision project D3 when the abnormality occurs in the process of the ERP system. In this way, the user does not need to fully understand the knowledge content, and the decision processing system 10 may pass on knowledge and experience, and may also ensure that the ERP system executes the business process according to management experience and methods, thereby improving operation efficiency.

FIG. 3A is a schematic diagram of an action of a decision processing system of an embodiment of the invention. Referring to FIG. 1 and FIG. 3A, the decision processing system 10 is operated during software design and establishes a plurality of heterogeneous data nodes N1 to N3 to illustrate the implementation details of step S220.

In the present embodiment, the processor 12 executes the data model 111 so that the data model 111 establishes a plurality of data nodes according to the target input data D1. The data nodes indicate various entities about the flow of abnormality to implement various business logic. The data nodes may include a data node N1′ indicated as “when task is opened”, a data node N2′ indicated as “option”, a data node N3′_1 indicated as “rule of thumb”, and a data node N3′_2 indicated as “evaluate by algorithm”.

In the present embodiment, the processor 12 executes the data model 111, so that the data model 111 structures the task metadata Dt into the plurality of heterogeneous data nodes according to the data nodes N1′ to N3′_2. The heterogeneous data nodes may include at least one timing node N1, at least one solution node N2, and at least one condition node N3 associated with each other.

In detail, the solution node N2 may be, for example, a data node indicated as “decision solution”, to indicate a certain solution and provide the user with a choice. The timing node N1 may, for example, be a data node indicated as “timing” to indicate when the solution (i.e., N2) is chosen. The condition node N3 may be, for example, a data node indicated as “basis” to indicate that the intervention of the solution is performed according to a certain rule. That is, there is an option relationship between the timing node N1 and the solution node N2, so that in a certain scenario, a certain solution may be used to process the corresponding abnormal event. In addition, there is an applicable relationship between the solution node N2 and the condition node N3, so as to standardize the flow of the solution via a certain rule.

For example, FIG. 3B is a schematic diagram of a plurality of heterogeneous data nodes of the embodiment of FIG. 3A of the invention. Referring to FIG. 3B, in an abnormal scenario of material shortage, the data model 111 provides a plurality of associated heterogeneous data nodes as possible processing logic. In the embodiment of FIG. 3B, the plurality of heterogeneous data nodes may include the timing node N1 indicated as “abnormal out of stock”, the condition node N3 indicated as “alternative supplier available”, and the solution node N2 indicated as “change supplier”. That is, in the above scenario, the processing logic may be, for example, to replace the supplier under the condition that there is an alternative supplier to rule out the abnormality of material shortage.

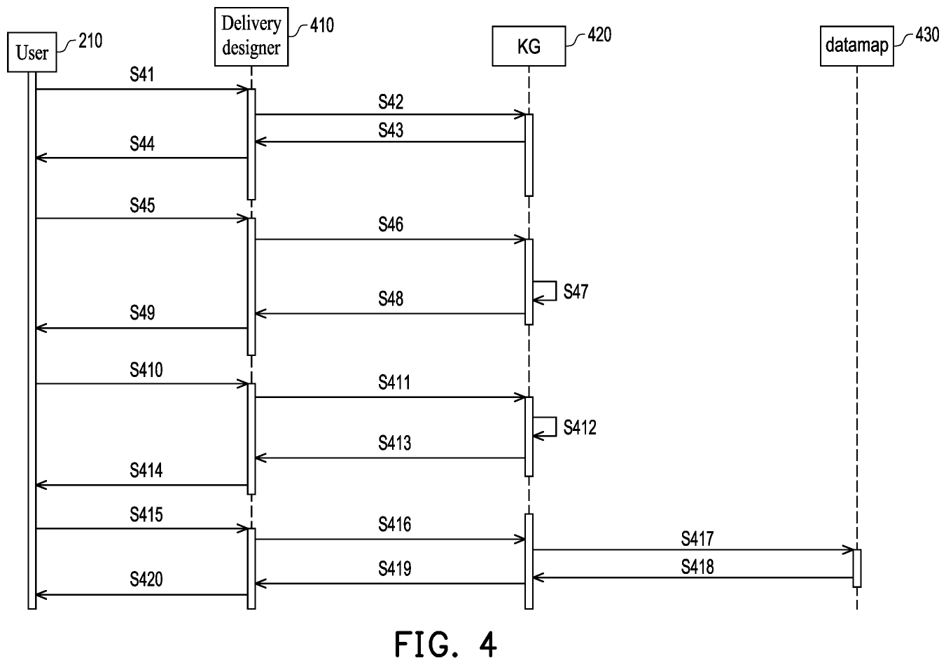

FIG. 4 is a schematic diagram of an action of a decision processing system of an embodiment of the invention. Referring to FIG. 1 and FIG. 4, the decision processing system 10 is operated during software design and interactively creates the decision project D3 with the user 210 to illustrate the implementation details of steps S220 to S230.

In the present embodiment, the memory 11 of the server 100 may also store a delivery designer 410, a mechanism designer (represented as “KG”) 420, and a mechanism tool (indicated as “datamap”) 430. The processor 12 may execute the tools 410 to 430 to implement various functions related to software design. In the present embodiment, the delivery designer 410, the mechanism designer 420, and the mechanism tool 430 may be configured to design the decision model 110.

In the present embodiment, the user 210 operates the electronic device 200 to interactively cooperate with the server 100. The decision processing system 10 may execute steps S41 to S420 by executing the processor 12. The order of the steps S41 to S420 is only an example for illustration, and is not limited thereto. In the present embodiment, the user 210 operates the electronic device 200 to log in the account in the server and the corresponding operation authority.

In step S41, the user 210 selects a new decision capability to the delivery designer 410 via the electronic device 200. The newly added decision capability indicates the newly established software design to design the decision project D3 that may solve the abnormal flow with respect to the target input data D1.

In step S42, the delivery designer 410 accesses the mechanism tool 420 to query the task list related to the target input data D1. The task list may, for example, be a list indicating various tasks. In step S43, the mechanism tool 420 returns a task list including manual type tasks to the delivery designer 410. The manual type tasks may, for example, indicate various tasks designed interactively with the server 100 by the user 210. In step S44, the delivery designer 410 returns the task list accessed in step S43 to the user 210, so that the electronic device 200 displays the task list. That is, the delivery designer 410 is able to set a mechanism on an abnormal flow, and guide the user 210 on the design operation of the mechanism via the task list.

In the present embodiment, the design decision model 110 (i.e., a plurality of components 410 to 430) selects a plurality of solution nodes (for example, the solution node N2 of FIG. 3B), a timing node (for example, the timing node N1 of FIG. 3B), and a plurality of condition nodes (for example, the condition node N3 of FIG. 3B) from the plurality of heterogeneous data nodes as the plurality of selected heterogeneous data nodes according to the selection instruction from the electronic device to accordingly encapsulate the heterogeneous data nodes into the decision project D3.

In detail, in step S45, the user 210 selects a task requiring a decision from the displayed task list via the electronic device 200, so as to design the required task in the decision project D3. In step S46, the delivery designer 410 receives a selection instruction from the electronic device 200 to access the identification of the selected task, and transmits the identification to the mechanism designer 420. This identification may for example be a unique identifier of the selected task and may be indicated as taskId.

In step S47, the mechanism designer 420 queries the valid data displayed in the identification of the browsing component (for example, pageview) according to the identification taskId of the task, so as to obtain the task metadata Dt related to the task of the target design. In step S48, the mechanism designer 420 returns the task metadata Dt conforming to the identification taskId to the delivery designer 410. In step S49, the delivery designer 410 returns the task metadata Dt accessed in step S48 to the user 210 so that the electronic device 200 displays a plurality of fields in the task metadata Dt. Such fields indicate various reference attributes in the task metadata Dt.

In step S410, the user 210 selects a scenario matching the target input data D1 from the displayed fields via the electronic device 200, so that the delivery designer 410 selects the scenario correspondingly. A scenario may for example be a field indicating how to trigger a task in the decision project D3. In the present embodiment, the scenario may be, for example, the timing node N1 as shown in FIG. 3B.

In step S411, the delivery designer 410 automatically selects a plurality of conditions associated with the selected scenario from a plurality of fields in the task metadata Dt according to the scenario. Such conditions may, for example, be rules or intervention conditions that enable or disable tasks. In the present embodiment, the condition may be, for example, the condition node N3 as shown in FIG. 3B.

In step S412, the mechanism designer 420 queries Encapsulating Security Payload (ESP) metadata in the data source according to the condition selected in step S411 to select and obtain a plurality of solutions related to the condition. Such scenarios may be, for example, process components of a task. In the present embodiment, the solution may be, for example, the solution node N2 as shown in FIG. 3B.

In step S413, the mechanism designer 420 returns the selected solution to the delivery designer 410. In step S414, the delivery designer 410 returns the solution accessed in step S413 to the user 210, so that the electronic device 200 displays the selected solution. In step S415, the user 210 confirms the solution via the electronic device 200, and instructs the server 100 to implement a validation mechanism for the solution.

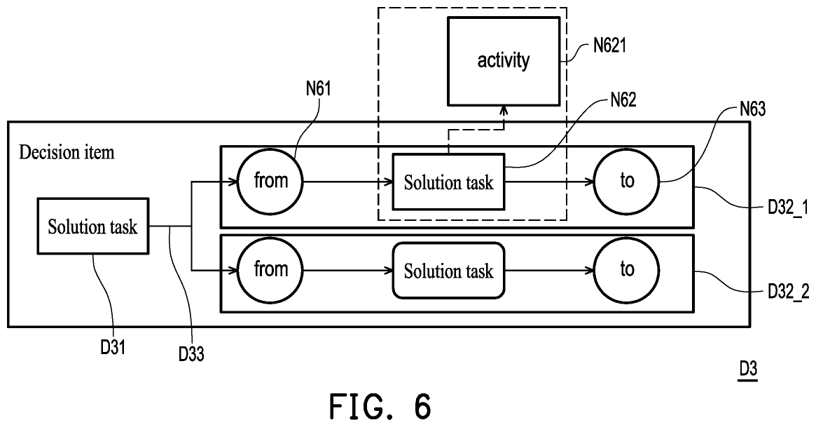

In step S416, the delivery designer 410 compiles the solution according to the instruction from the electronic device 200 to generate an executable task (for example, a solution task D31 shown in FIG. 6). In step S417, the mechanism designer 420 performs a second compilation on the executable task to generate the executable decision project D3 (for example, the decision project D3 shown in FIG. 6).

In step S418, the mechanism tool 430 generates corresponding mechanism logic (mechanismLogic) according to the decision project D3 generated in step S417 to complete the encapsulation operation of the decision project D3. In step S419, the mechanism designer 420 saves a portion of the parts of the mechanismLogic. In step S420, the delivery designer 410 returns an execution end message to the user 210, so that the electronic device 200 displays a valid result message.

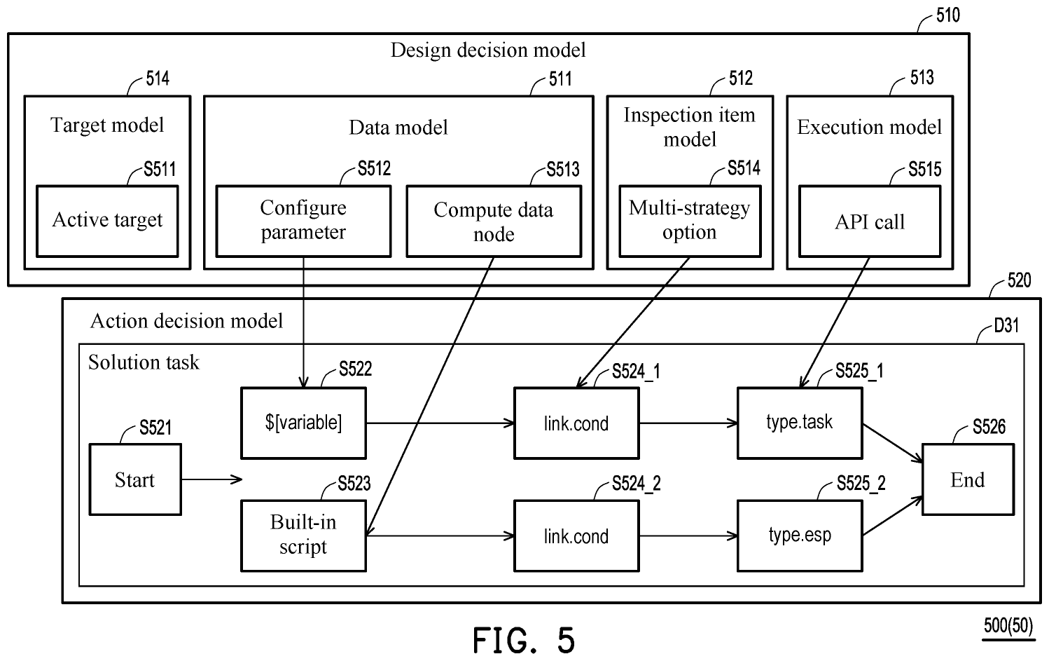

FIG. 5 is a schematic diagram of an action of a decision processing system of another embodiment of the invention. Referring to FIG. 5, a decision processing system 50 may include a server 500 and an electronic device. The server 500 may include a processor and a memory, wherein the memory may store a design decision model 510 and an action decision model 520. In the embodiment of FIG. 5, the design decision model 510 may include a target model 514, a data model 511, an inspection item model 512, and an execution model 513. The action decision model 520 may access and execute the solution task D31. The data model 511, the inspection item model 512, the execution model 513, and the action decision model 520 are as provided in the relevant description of the decision processing system 10 and analogized as such, and are therefore not repeated herein.

In the present embodiment, the server 500 accesses an event (e.g., the target input data D1 of FIG. 1) from the electronic device by executing the design decision model 510. The execution design decision model 510 generates the executable solution task D31 (for example, the task selected in step S45 of FIG. 4) according to the above event, so that the action decision model 520 executes the solution task D31 according to the above event. Moreover, the execution design decision model 510 generates an executable decision project (for example, the decision project D3 designed and completed in steps S46 to S20 in FIG. 4) according to the above event and the solution task D31.

In the present embodiment, the target model 514 executes a module S511, so that the target model 514 controls the mount point of the active target. The active target may be, for example, a data source provided by an electronic device to provide raw data supply. The active target may be, for example, the target input data D1 and/or the application input data D2 of FIG. 1. The mount point controlled by the target model 514 may be a task (such as the solution task D31) or an project (such as the decision project D3), and may be, for example, a task or an project based on data-driven programming.

In the present embodiment, the data model 511 executes a module S512, so that the data model 511 generates a plurality of active data nodes according to a plurality of configured parameters of each of the target input data D1 and the task metadata (for example, the data Dt of FIG. 1). In detail, the data model 511 configures parameters of the target input data D1 and configures parameters of the accessed task metadata Dt. The data model 511 configures the parameters to create a plurality of active data nodes. That is, the data model 511 may deconstruct the parameters in the target input data D1 and the task metadata Dt and the coupling relationship between the parameters, and represent the deconstruction result as a plurality of data nodes.

In the present embodiment, the data model 511 executes a module S513 so that the data model 511 computes a plurality of active data nodes in the module S512 according to a built-in data processing tool (e.g., defined formula) to generate a computing result. The computing result may be expressed, for example, by a plurality of corresponding active data nodes. That is, the data model 511 processes data with reference to formulas, and expresses the computing result as a plurality of data nodes.

In the present embodiment, the inspection item model 512 executes a module S514, so that the data model 511 computes a plurality of active data nodes with reference to a plurality of multi-strategy options to generate a plurality of link data nodes. Specifically, the inspection item model 512 refers to a plurality of multi-strategy options in the task metadata Dt, and computes the computing result (i.e., a plurality of active data nodes) from the data model 511 to establish a plurality of link data nodes. The inspection item model 512 computes the link data nodes to generate a check result that represent normal or abnormal. In the present embodiment, the plurality of multi-strategy options may, for example, be computing formulas with different conditional expressions. The multi-strategy options may correspond to one or a plurality of check results. The plurality of link data nodes may, for example, be selection logic associated with a gateway routing node.

It should be noted that the inspection item model 512 may deposit a batch of valuable management knowledge (for example, a plurality of link data nodes) via a knowledge graph. The inspection item model 512 may correct the process associated with the target input data D1 via the processed control data (for example, a plurality of multi-strategy options) and the above management knowledge, and express it as a check result.

In the present embodiment, the execution model 513 executes a module S515, so that the execution model 513 establishes a plurality of operation execution nodes in the form of an API call according to the target expected data (for example, the operation library 1131 of FIG. 1), and encapsulates a plurality of active data nodes in the module

S512, a plurality of link data nodes in the module S514, and the operation execution nodes into a plurality of solution tasks (FIG. 5 adopts a single solution task D31 as an example) in the decision project D3.

In the present embodiment, the execution of the solution task D31 starts from the module S521 and ends from the module S526. The action decision model 520 executes the module S522 corresponding to the module S512 to configure the parameters of the target input data D1 and the task metadata Dt and list the parameters into a plurality of active data nodes. The action decision model 520 executes the module S523 corresponding to the module S513 to compute the plurality of active data nodes with reference to formulas and build the computing result into a script (i.e., active data nodes). The action decision model 520 executes the modules S524_1 to S524_2 corresponding to the module S514 to list a plurality of multi-strategy options, and checks the plurality of active data nodes according to the multi-strategy options to generate a plurality of link data nodes. The action decision model 520 executes the modules S525_1 to S525_2 corresponding to the module S515 to execute or re-initiate the solution task D31 via an API call.

FIG. 6 is a schematic diagram of a decision project of an embodiment of the invention. Referring to FIG. 5 and FIG. 6, during the software design period, the decision processing system 50 interactively designs the decision project D3 that may solve the abnormal process with the user. In the embodiment of FIG. 6, the decision project D3 may include a plurality of solution tasks D31 and D31_1 to D32_2 and a plurality of links D33. The decision processing system 50 may design the corresponding solution tasks D31 and D32_1 to D32_2 via the plurality of modules S511 to S515 in FIG. 5.

In the present embodiment, the decision processing system 50 executes the design decision model 510, so that the design decision model 510 calls the target expected data (for example, the operation library 1131 of FIG. 1) via an API to obtain a plurality of software components that may resolve the abnormality. Such software components may include a source Widget component, a StrategyWidget component, a choose Widget component, and a planWidget component. The software components may serve as a plurality of operation execution nodes in the module S515.

In detail, the design decision model 510 executes the source Widget component to generate a task model (for example, a model corresponding to the solution task D32_1) by default. In the model corresponding to the solution task D32_1, the source Widget component generates a data node N61 denoted as “from” and a data node N63 denoted as “to” as the flow of data status. In addition, the sourceWidget component generates a data node N62 denoted “solution task”. The source Widget component presets the attribute of the data node N62 as flowGraph, so that the data node N62 includes a child data node N621 denoted as “activity”. The design decision model 510 performs an encapsulation operation on the data nodes N61 to N63 to generate the solution task D32_1. Another solution task D32_2 is as provided in the description of the solution task D32_1 and be deduced by analogy.

In the present embodiment, the decision processing system 50 executes the design decision model 510, so that the design decision model 510 forms a plurality of links D33 among the plurality of solution tasks D31 and D32_1 to D32_2 according to a plurality of condition nodes (for example, the condition node N3 of FIG. 3B) in a plurality of heterogeneous data nodes, to describe the implementation details of steps S410 to S415 with examples.

In detail, the design decision model 510 executes the StrategyWidget component to generate a plurality of selection data having various conditions via the choose Widget component. The design decision model 510 executes the Strategy Widget component to generate gateway attribute data corresponding to the plurality of solution tasks D31 and D32_1 to D32_2 via the planWidget component. The design decision model 510 executes the Strategy Widget component to generate the plurality of links D33 according to the above plurality of selection data and gateway attribute data corresponding to the plurality of solution tasks D31 and D32_1 to D32_2.

In the present embodiment, the link D33 having the first condition may be, for example, linked between the solution task D31 and the solution task D32_1. The link D33 having the second condition may be, for example, linked between the solution task D31 and the solution task D32_2. That is, for the solution task D31, the plurality of links D33 having selection conditions (for example, whether the amount is sufficient) may correspond to different recommendation processes, so as to lead to different solution tasks D32_1 and D32_2 respectively.

In the present embodiment, the decision processing system 50 executes the design decision model 510, so that the design decision model 510 encapsulates the plurality of solution tasks D31 and D32_1 to D32_2 and the plurality of links D33 into the decision project D3 according to the timing node (for example, the timing node N1 of FIG. 3B) in a plurality of heterogeneous data nodes, to describe the implementation details of steps S416 to S417 with examples.

In detail, when the design decision model 510 executes overall compilation, the design decision model 510 invokes another mechanism target. At this time, the design decision model 510 links the plurality of solution tasks D31 and D32_1 to D32_2 and the plurality of links D33 in the project model corresponding to the timing nodes via three decision elements (that is, timing node, solution node, and condition node), to form the compiled code (i.e., the decision project D3).

Based on the above, the decision processing system and the decision processing method of the invention may precipitate and encapsulate the abnormal process with the knowledge graph, so as to implement the inheritance of knowledge and experience. Moreover, the decision processing system interactively designs the executable decision project according to the plurality of heterogeneous data nodes via the server and the user, and may eliminate the corresponding abnormality based on the decision project when the process of the ERP system is abnormal. In this way, the decision processing system may pass on knowledge and experience, and may also create the decision project suitable for the abnormal situation to improve operation efficiency.

Lastly, it should be noted that: the above embodiments are only used to illustrate the technical solutions of the invention, rather than to limit them. Although the invention has been described in detail with reference to the above embodiments, those of ordinary skill in the art should understand that: the technical solutions described in the above embodiments may still be modified, or equivalent replacements for some or all of the technical features may be performed. However, these modifications or replacements do not make the essence of the corresponding technical solutions depart from the scope of the technical solutions of the embodiments of the invention.

What is claimed is:

1. A decision processing system, comprising:
an electronic device acquiring target input data and application input data; and
a server coupled to the electronic device and comprising a memory and a processor, wherein the memory stores a plurality of models and task metadata, the processor is coupled to the memory and executes the plurality of models, and the plurality of models comprise a design decision model and an action decision model,
wherein the design decision model computes the task metadata according to the target input data to generate a plurality of heterogeneous data nodes, and executes an encapsulation operation on the plurality of selected heterogeneous data nodes to generate a decision project,
wherein the action decision model executes the decision project according to the application input data to generate a decision result to the electronic device.

2. The decision processing system of claim 1, wherein the plurality of heterogeneous data nodes comprise at least one solution node, at least one timing node, and at least one condition node associated with each other.

3. The decision processing system of claim 1, wherein the design decision model selects a plurality of solution nodes, a timing node, and a plurality of condition nodes from the plurality of heterogeneous data nodes as the plurality of selected heterogeneous data nodes according to a selection instruction from the electronic device.

4. The decision processing system of claim 1, wherein the design decision model comprises a data model, an inspection item model, and an execution model,
wherein the data model generates a plurality of active data nodes according to a plurality of configured parameters of each of the target input data and the task metadata,
wherein the inspection item model computes the plurality of active data nodes with reference to a plurality of multi-strategy options to generate a plurality of link data nodes,
wherein the execution model generates a plurality of operation execution nodes according to target expected data, and encapsulates the plurality of active data nodes, the plurality of link data nodes, and the plurality of operation execution nodes into a plurality of solution tasks in the decision project.

5. The decision processing system of claim 4, wherein the design decision model forms a plurality of links between the plurality of solution tasks according to a plurality of condition nodes in the plurality of heterogeneous data nodes.

6. The decision processing system of claim 5, wherein the design decision model encapsulates the plurality of solution tasks and the plurality of links into the decision project according to a timing node in the plurality of heterogeneous data nodes.

7. A decision processing method, comprising:
acquiring target input data and application input data via an electronic device; and
executing a plurality of models stored in a memory of a server via a processor of the server, wherein the plurality of models comprise a design decision model and an action decision model, comprising:
computing task metadata stored in the memory according to the target input data via the design decision model to generate a plurality of heterogeneous data nodes;
executing an encapsulation operation on the plurality of selected heterogeneous data nodes via the design decision model to generate a decision project; and
executing the decision project according to the application input data via the action decision model to generate a decision result to the electronic device.

8. The decision processing method of claim 7, wherein the plurality of heterogeneous data nodes comprise at least one solution node, at least one timing node, and at least one condition node associated with each other.

9. The decision processing method of claim 7, wherein the step of executing the plurality of models further comprises:
selecting a plurality of solution nodes, a timing node, and a plurality of condition nodes from the plurality of heterogeneous data nodes as the plurality of selected heterogeneous data nodes according to a selection instruction from the electronic device via the design decision model.

10. The decision processing method of claim 7, wherein the design decision model comprises a data model, a inspection item model, and an execution model, and the step of executing the plurality of models further comprises:
generating a plurality of active data nodes according to a plurality of configured parameters of each of the target input data and the task metadata via the data model;
computing the plurality of active data nodes with reference to a plurality of multi-strategy options to generate a plurality of link data nodes via the inspection item model;
generating a plurality of operation execution nodes according to target expected data via the execution model; and
encapsulating the plurality of active data nodes, the plurality of link data nodes, and the plurality of operation execution nodes into a plurality of solution tasks in the decision project via the execution model.

11. The decision processing method of claim 10, wherein the step of executing the plurality of models further comprises:
forming a plurality of links between the plurality of solution tasks according to a plurality of condition nodes in the plurality of heterogeneous data nodes via the design decision model.

12. The decision processing method of claim 11, wherein the step of executing the plurality of models further comprises:
encapsulating the plurality of solution tasks and the plurality of links into the decision project according to a timing node in the plurality of heterogeneous data nodes via the design decision model.
